(19) United States
(12) Patent Application Publication
(10) Pub. No.: US 2026/0143769 A1
(43) Pub. Date: May 21, 2026

(54) EPITAXY SHAPES IN SOURCE/DRAIN REGION

(71) Applicant: Taiwan Semiconductor Manufacturing Co., Ltd., Hsinchu (TW)

(72) Inventors: Yan-Ting Lin, Baoshan Township (TW); Chien-I Kuo, Zhubei City (TW); Ming-Hua Yu, Hsinchu City (TW); Chii-Horng Li, Zhubei City (TW)

(21) Appl. No.: 18/949,454

(22) Filed: Nov. 15, 2024

(51) Int. Cl. H01L 29/167; H01L 29/04; H01L 29/06; H01L 29/423; H01L 29/66; H01L 29/775; H01L 29/786

(52) U.S. Cl. CPC H10D 62/834; H10D 30/014; H10D 30/43; H10D 30/6713; H10D 30/6757; H10D 62/121; H10D 62/405; H10D 30/6735

(57) ABSTRACT

In some embodiments, a semiconductor device is described that includes a substrate having a (110) crystal orientation; a stack of nanostructures over the substrate; and a source/drain region in trenches on opposing sides of the stack of nanostructures. In some embodiments, the source/drain region includes a first semiconductor material having a first concentration of germanium on ends of the nanostructures in the stack of nanostructures. The first semiconductor material has a triangular geometry when viewed from a side cross sectional view. In some embodiments, the source/drain region also includes a second semiconductor material having a second concentration of germanium on the first semiconductor material filling at least a portion of the trenches. The second concentration of the germanium is greater than the first concentration of the germanium.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments; and

FIGS. 2, 3, 4, 5A, 5B, 6A, 6B, 7A, 7B, 7C, 8A, 8B, 9A, 9B, 10A, 10B, 10C, 10D, 11A, 11B, 11C, 11D, 11E, 11F, 11G, 12A, 12B, 13A, 13B, 14A, 14B, 15A, 15B, 15C, 16A, 16B, 16C, 17A, 17B, 17C, 18A, 18B, and 18C are cross-sectional views of intermediate stages in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The performance of p-type semiconductor device, such as p-type field effect transistors (including p-type nanostructure devices including gate all around (GAA) gate structures) can be highly relative to hole mobility. Substrate orientation and fin direction can also impact hole mobility to increase device performance. For example, a substrate orientation and fin direction, of <110>/(001) generally has lesser hole mobility than <110>/(110). In various embodiments, the methods and structures that are described herein employ a (110) substrate to provide for enhanced charge carrier mobility, and provides a further performance benefit by controlling epitaxially deposited shapes in PMOS source/drain region on (110) substrate. For example, for the epitaxially deposited material for the source/drain regions, the shape of the epitaxially deposited material can be controlled to have a triangular geometry by adjusting the process conditions of the epitaxial growth process. By controlling the shape of the epitaxial material, the contact surfaces of the metal contact for the source/drain regions may be maximized, allowing the metal contact to land on epitaxial material having a highest concentration of germanium. In some embodiments, the larger contact area on high germanium concentration portions of the p-type epitaxial material of the source/drain regions result in lower contact resistivity.

Embodiments are described below in a particular context, a die comprising nano-FETs. Various embodiments may be applied, however, to dies comprising other types of transistors (e.g., stacking transistors, or the like) in lieu of or in combination with the nano-FETs.

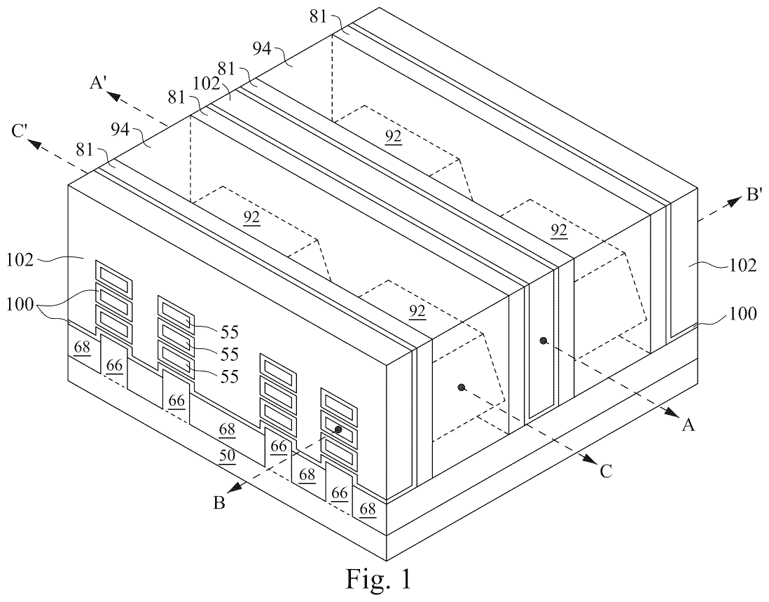

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowire, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. STI regions 68 (also referred to as STI structures or STI regions) are disposed between adjacent fins 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

FIG. 1 further illustrates reference cross-sections that are used in later figures. Cross-section A-A′ is along a longitudinal axis of a gate electrode and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

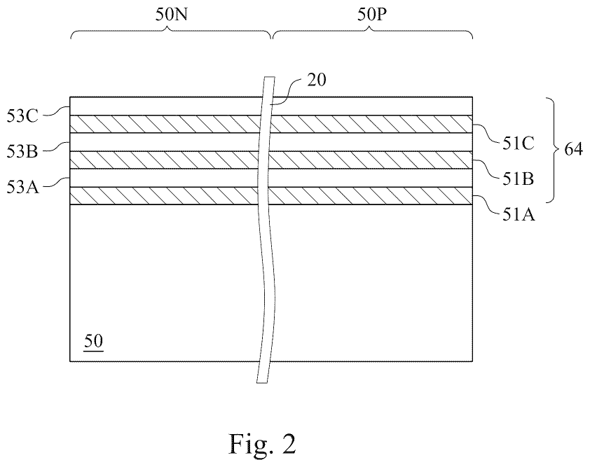

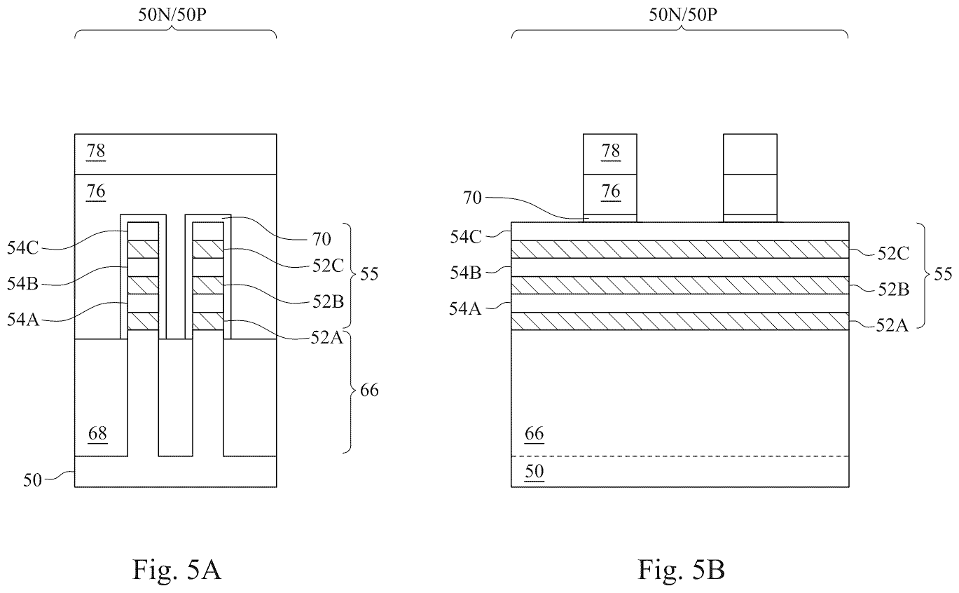

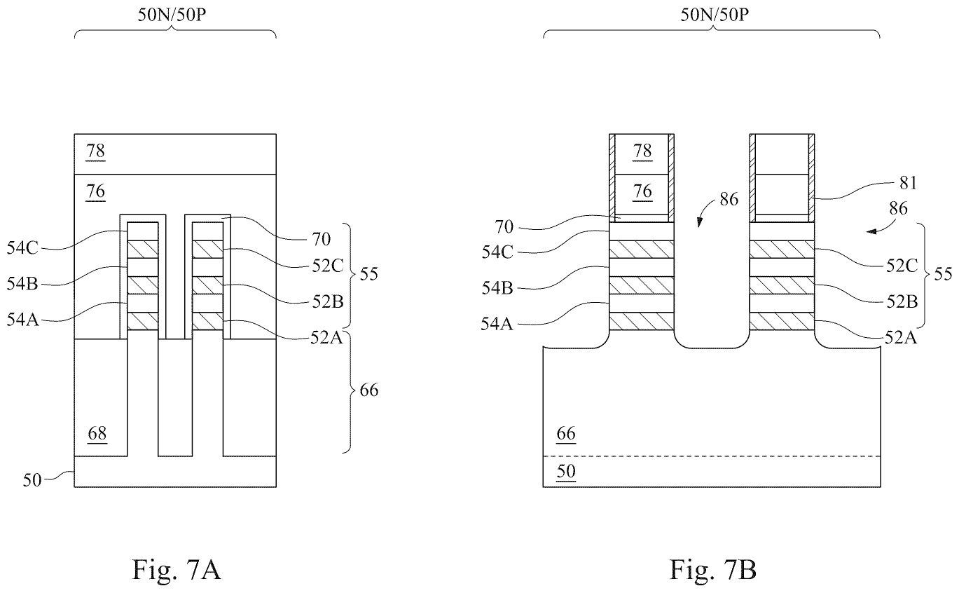

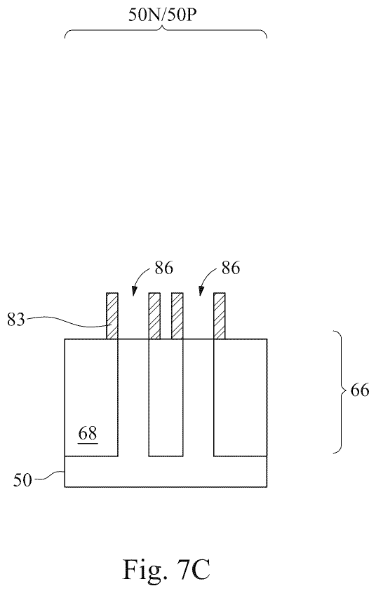

FIGS. 2 through 18C are cross-sectional views of intermediate stages in the manufacturing of nano-FETs, in accordance with some embodiments. FIGS. 2 through 5A, 6A, 7A, 8A, 9A, 10A, 11A, 12A, 13A, 14A, 15A, 16A, 17A and 18A illustrate reference cross-section A-A′ illustrated in FIG. 1. FIGS. 5B, 6B, 7B, 8B, 9B, 10B, 10C, 11B, 11C, 11D, 11E, 11F, 11G, 12B, 13B, 14B, 15B, 15C, 16B, 17B, 18B and 18C illustrate reference cross-section B-B′ illustrated in FIG. 1. FIGS. 7C, 16C and 17C illustrate reference cross-section C-C′ illustrated in FIG. 1.

In FIG. 2, a substrate 50 is provided. The substrate 50 may be a semiconductor substrate, such as a bulk semiconductor. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

In some embodiments, the substrate 50 may be composed of silicon (Si) having a wafer crystalline orientation of (110). In some embodiments, forming a (110) for a silicon substrate may include a crystalline orientation growth process that includes crystal growth, orientation control, slicing, polishing/cleaning and verification. Crystalline growth can begin with the Czochralski method. In the Czochralski method, a single crystal silicon ingot it grown from a seed crystal. The seed crystal is carefully orientated to ensure the desired (110) plane is achieved. During crystal growth, the seed crystal is aligned with the (110) plane. This alignment determines the orientation of the entire ingot. Once, the ingot is grown, the ingot may be sliced into thin wafers using a diamond wire saw. For example, slicing can be done perpendicular to the (110) plane to ensure that the wafers have the correct orientation. In a following step, the wafers may be polished to achieve a smooth surface and cleaned to remove any contaminants. In some embodiments, X-ray diffraction may be employed to ensure that the correct (110) orientation is in the wafer. In some embodiments, a (110) orientation on a silicon substrate may be provided using molecular beam epitaxy (MBE).

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or the another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

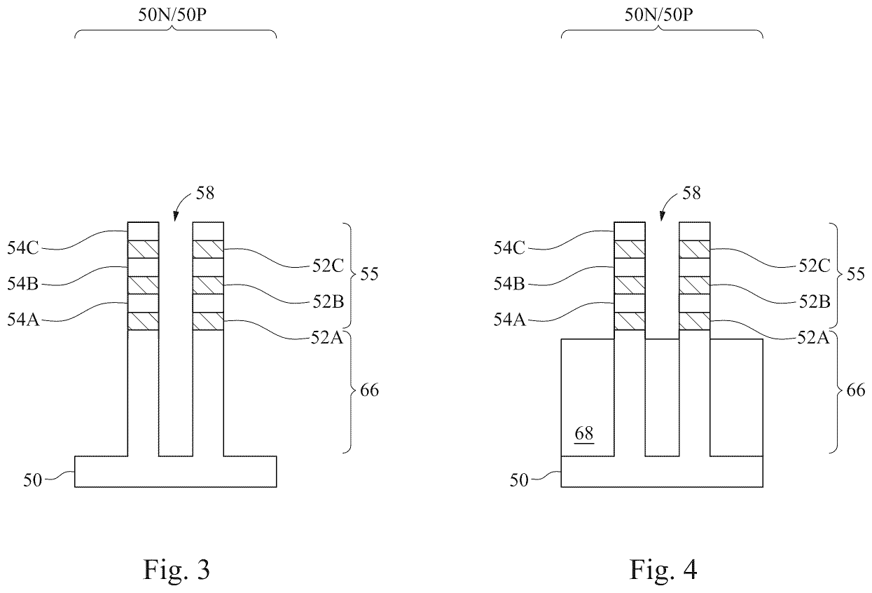

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments (not separately illustrated), the hard mask 56 may be a multi-layer structure. The hard mask 56 may be formed over the nanostructures 55 using an acceptable process(es) such as thermal oxidation, physical vapor deposition (PVD), CVD, ALD, combinations thereof, or the like.

In some embodiments, the fins 66 and the nanostructures 55 may be formed using an epitaxial deposition surface on the substrate 50 having the (110) crystalline orientation. Epitaxially forming the fins 66 and the nanostructures 55 on the substrate 50 having the (110) crystalline orientation means the growth of a semiconductor material on a deposition surface of a semiconductor material, in which the semiconductor material being grown has substantially the same crystalline characteristics as the semiconductor material of the deposition surface, e.g., the substrate 50 having the (110) crystalline orientation. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, the epitaxial material for the fins 66 and the nanostructures 55 that is epitaxially deposited on the (110) crystal surface of the substrate 50 will take on a (110) orientation.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In some embodiments, the nanostructures 55 are etched to provide at least that the second nanostructures 54 to have a fin direction that is <110>. The fin direction (also referred to channel direction) is defined by the path that the charge carriers, e.g., minority charge carriers (e.g., holes) in p-type device, take from the source to drain regions. The nanostructures 55 have the (110) crystal plane, and be orientated along a fin direction that is <110>.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates are formed over and along sidewalls of the nanostructures 55 and the fin 66. To form the dummy gates, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

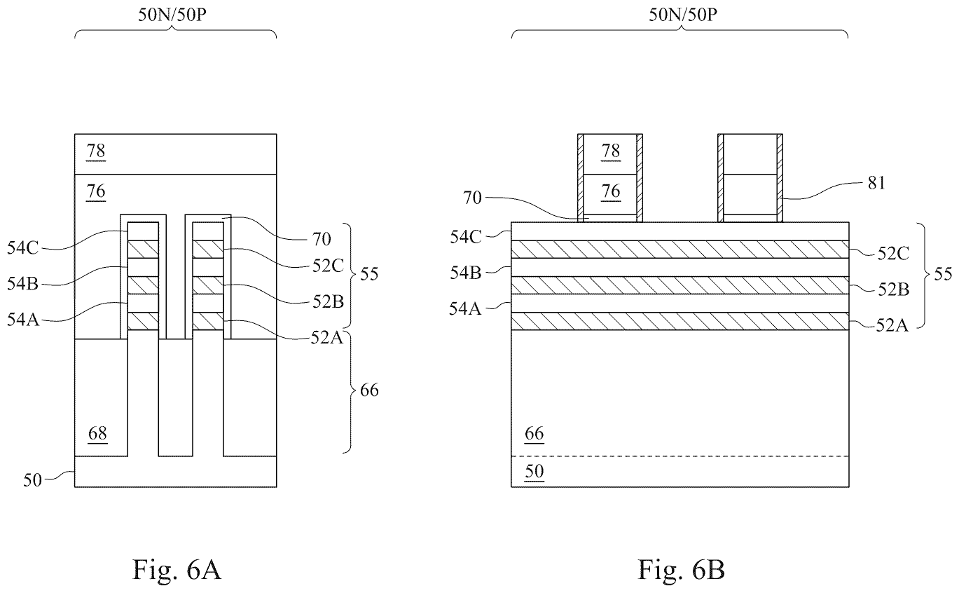

In FIGS. 6A and 6B, gate spacers 81 are formed over the nanostructures 55 and the STI regions 68, on exposed sidewalls of the masks 78 (if present), the dummy gates 76, and the dummy dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

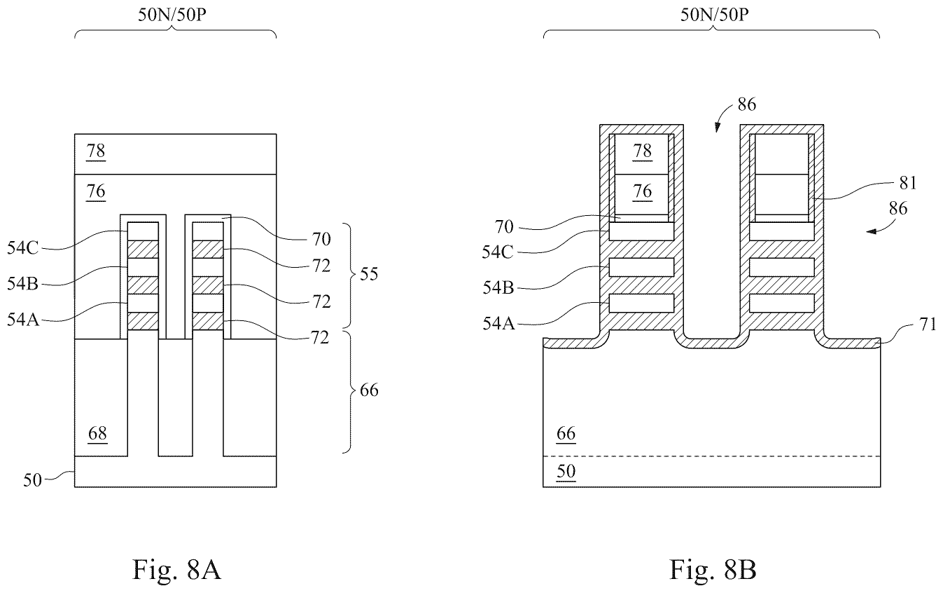

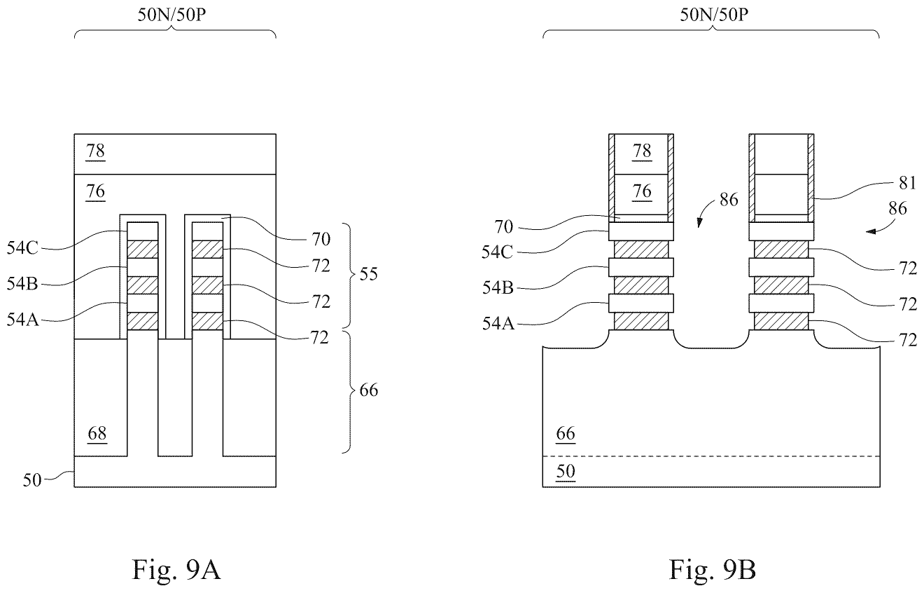

In FIGS. 8A-9B, the first nanostructures 52 are replaced with a sacrificial material 72 (also referred to as disposable oxide interposers (DOI) 72). Replacing the first nanostructures 52 may include etching away the first nanostructures 52 using a suitable etch process, such as an isotropic etch process, that is performed through the first recesses 86 as illustrated by FIGS. 8A-8B. The etch process may be selective to the material of the first nanostructures 52 and remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

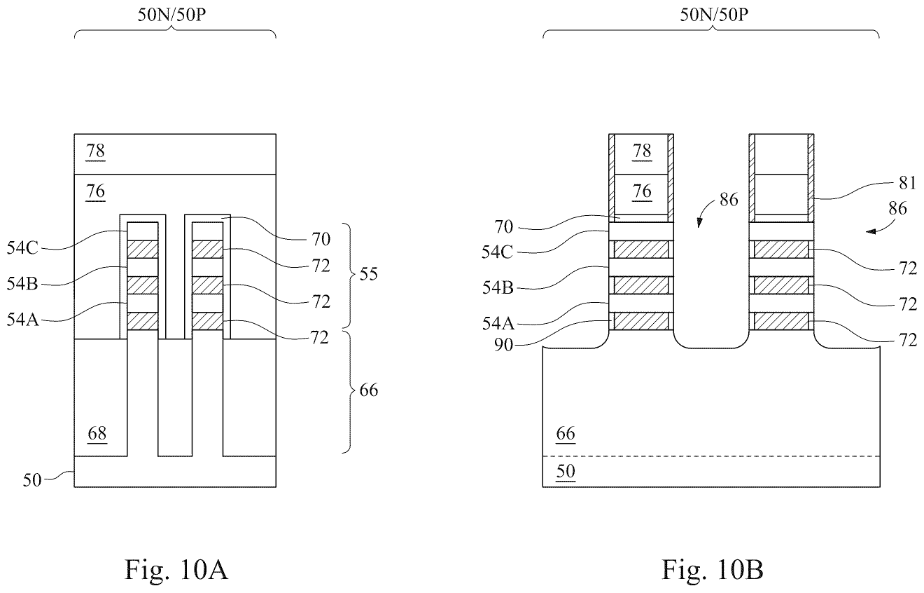

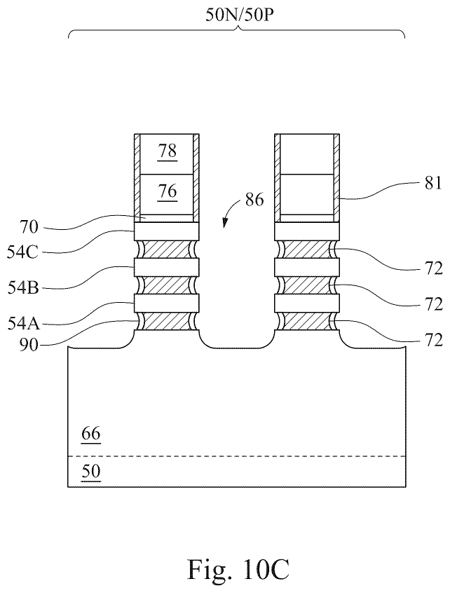

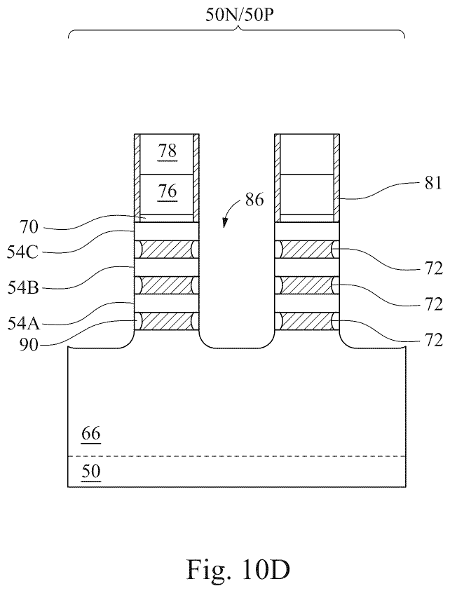

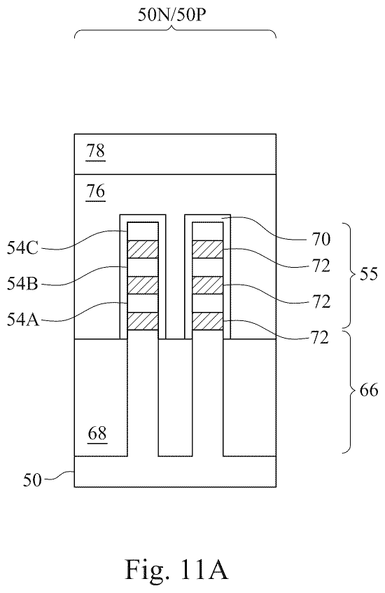

Subsequently, a sacrificial material layer 71 is deposited in the recesses 86 and spaces where the first nanostructures 52 were removed. The sacrificial material layer 71 may be deposited by a conformal deposition process, such as CVD, ALD, or the like. The sacrificial material layer may comprise an insulating material such as silicon oxide (e.g., SiO₂), or the like that can be selectively etched from the second nanostructures 54. In FIGS. 9A-9B, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the nanostructures 54. Although sidewalls of sacrificial material 72 are illustrated as being straight in FIG. 9B, the sidewalls may be concave or convex (see e.g., FIG. 10C).

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 74, germanium residue may remain in channel regions of the resulting transistor devices, which negatively affects the performance of the channel regions. By replacing the first nanostructures 52 with an insulating material prior to the high temperature processes (e.g., source/drain annealing), manufacturing defects can be reduced and device performance can be improved (e.g., increased current drive, reduced capacitance, and improved short channel effect).

In FIGS. 10A and 10B, inner spacers 90 are formed in the recesses 86 on the sidewalls of the sacrificial material 72. The inner spacers 90 act as isolation features between subsequently formed source/drain regions and a gate structure. As will be discussed in greater detail below, source/drain regions will be formed in the recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 9A and 9B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54 (see e.g., FIG. 10C). Moreover, although the outer sidewalls of the inner spacers 90 are illustrated as being straight in FIG. 10B, the outer sidewalls of the inner spacers 90 may be concave or convex. As an example, FIG. 10C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 10D illustrates an embodiment in which sidewalls of the sacrificial material 72 are concave, outer sidewalls of the inner spacers 90 are straight, and the inner spacers 90 are flush with sidewalls of the second nanostructures 54.

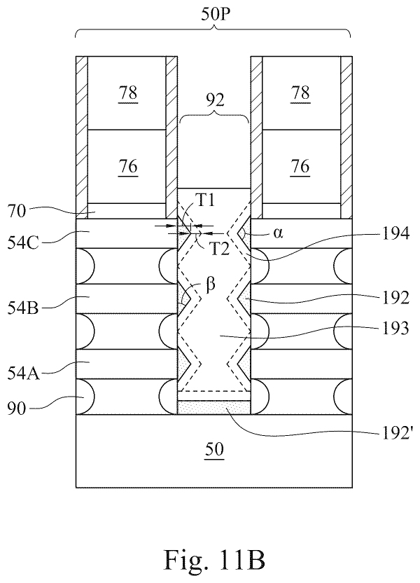

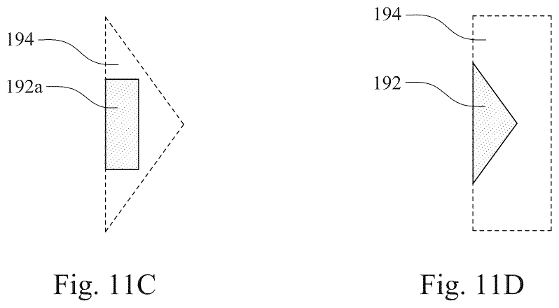

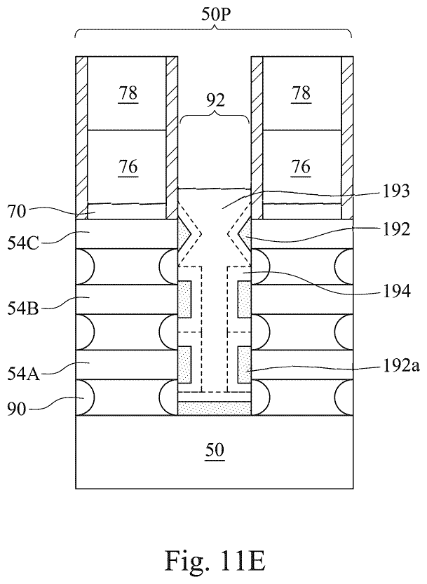

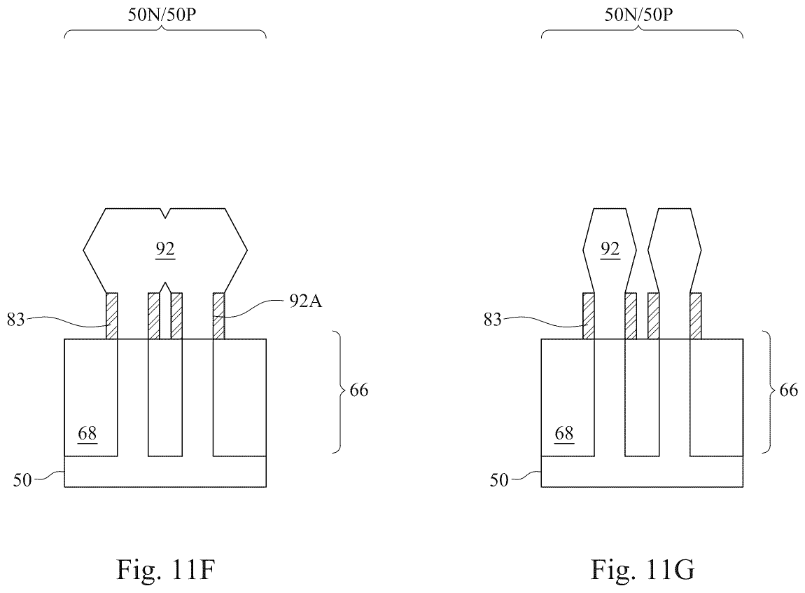

In FIGS. 11A-11G, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance.

As illustrated in FIG. 11B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The n-type and/or p-type impurities for source/drain regions may be any of the impurities previously discussed. In some embodiments, the epitaxial source/drain regions 92 may be in situ doped during growth.

In some embodiments, forming the epitaxial source/drain region 92 for the p-type region 50P can include forming three semiconductor material compositions, which can include a first semiconductor material 192, a second semiconductor material 193, and an interface semiconductor material 194 that is present between the first and second semiconductor materials 193, 194.

In some embodiments, the first semiconductor material 192 may be epitaxially formed on a first semiconductor material 192 having a first concentration of germanium on ends of nanostructures at sidewalls of the trench, in which the first semiconductor material 192 has a triangular geometry when viewed from a side cross sectional view. The trench is provided by the first recesses 86, which expose an upper surface of the substrate having the (110) crystal plane.

In some embodiments, the second nanostructures 54 are composed of silicon, and the first semiconductor material 192 is composed of silicon germanium. The triangular geometry for the first semiconductor material 192 that is on the edges (sidewalls) of the second nanostructures 54 may be formed using an epitaxial deposition process, in which the conditions of the epitaxial deposition process may be adjusted to control the geometry of the deposited material. In some embodiments, the geometry of the first semiconductor material 192 may be adjusted to have a particular shape (e.g., triangular, e.g., three sided cross-sectional geometry) by adjusting the temperature of the epitaxial deposit process.

Epitaxially forming the first semiconductor material 192 on the edges of the second nanostructures 54 means the growth of a semiconductor material on a deposition surface of a semiconductor material, in which the semiconductor material being grown has substantially the same crystalline characteristics as the semiconductor material of the deposition surface, e.g., the edges of the second nanostructures 54. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a (110) crystal surface will take on a (110) orientation. For example, being that the second nanostructures have a (110) crystal orientation, the first semiconductor material 192 may have a (110) crystal orientation.

In some embodiments, a number of different sources may be used for the epitaxial deposition of the semiconductor material that forms the first semiconductor material 192. In some embodiments, in which the first semiconductor material 192 is composed of silicon germanium (SiGe), the silicon gas source for epitaxial deposition may include at least one of hexachlorodisilane (Si₂Cl₆), tetrachlorosilane (SiCl₄), dichlorosilane (Cl₂SiH₂), trichlorosilane (Cl₃SiH), methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄), hexamethyldisilane ((CH₃)₆Si₂) and combinations thereof. In some embodiments, the germanium gas source for epitaxial deposition of the first semiconductor material 192 composed of silicon germanium may include at least one of germane (GeH₄), digermane (Ge₂H₆), halogermane, dichlorogermane, trichlorogermane, tetrachlorogermane and combinations thereof.

In some embodiments, the concentration of germanium (Ge) in the silicon germanium (SiGe) material of the first semiconductor material 192 may be selected to provide a Si₁₋ₓGeₓ composition, in which 0<x<0.1. The concentration of germanium (Ge) for the first semiconductor material 192 may be less than the germanium (Ge) concentration in the subsequently formed second semiconductor material 193 having a second concentration of germanium, and the interface semiconductor material 194. In some embodiments, to provide the triangular side cross-sectional geometry, the temperature of the epitaxially deposition for forming the first semiconductor material 192 is limited to be less than 600° C.

Referring to FIG. 11B, in some embodiments, the triangular side cross-sectional geometry includes a base angle β ranging from 35 degrees to 55 degrees. In an embodiment, the triangular side cross-sectional geometry includes a base angle β of 45 degrees, e.g., 45 degrees +−10 degrees. In the example, depicted in FIG. 11B, the base angle β is equal to 45 degrees, and the apex angle for the triangular side cross-sectional geometry is equal to 90 degrees.

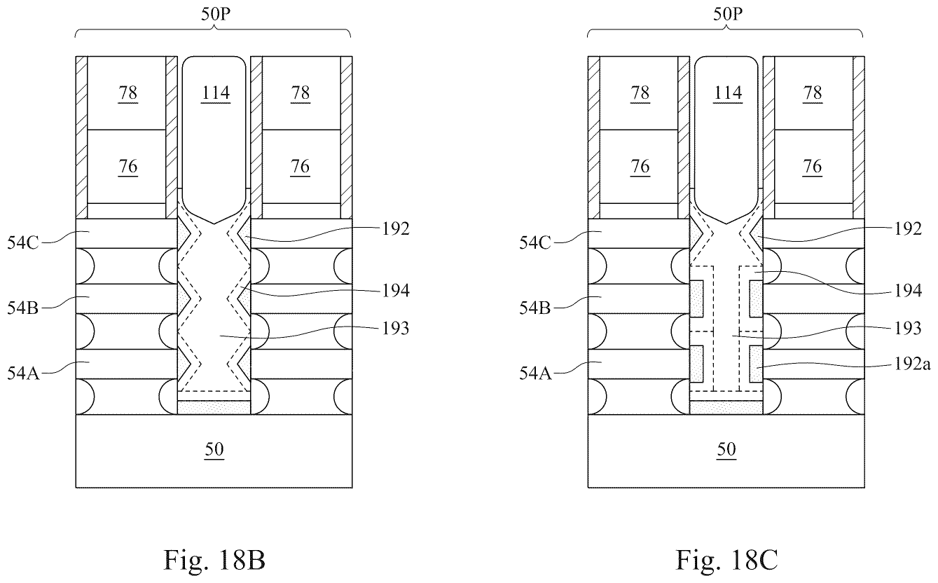

The first semiconductor material 192 for the p-type region 50P may be doped with a p-type dopant. For example, for a group IV semiconductor, such as silicon (Si) and silicon germanium (SiGe), examples of p-type dopants can include boron, indium, and/or gallium. In some embodiments, the concentration of the p-type dopant for the first semiconductor material 192 is less than the concentration of the second semiconductor material 193, and the interface semiconductor material 194. In one example, the p-type dopant concentration of the first semiconductor material 192 may range from to 1×10²⁰ cm⁻³ to 3×10²⁰ cm⁻³. In some embodiments, the p-type dopant concentration of the third semiconductor material 192a depicted in FIG. 18C may range from 1×10²⁰ cm⁻³ to 3×10²⁰ cm⁻³. The second semiconductor material 193 may range from 7×10²⁰ cm⁻³ to 1×10²¹ cm⁻³. In some embodiments, the interface semiconductor material 194 may range from 3×10²⁰ cm⁻³ to 7×10²⁰ cm⁻³. In some embodiments, the thickness T1 of the first semiconductor material 192 as measured from the edge of the second nanostructures 54 to the apex of the triangular side cross-sectional geometry of the first semiconductor material 192 may range from 2 nm to 10 nm. In an example, the thickness T1 of the first semiconductor material 192 as measured from the edge of the second nanostructures 54 to the apex of the triangular side cross-sectional geometry of the first semiconductor material 192 may range from 2 nm to 4 nm.

FIG. 11B illustrates that the first semiconductor material 192 is formed on each end of the second nanostructures 54 on the sidewalls of the trench provided by the first recesses 86. A first epitaxial material base portion 192′ may be present at the base of the trench directly on a surface of the substrate 50 having the (110) crystalline orientation.

It is noted that FIG. 11B only represents one embodiment of the geometry of the first semiconductor material 192. It is not necessary that the semiconductor material epitaxially formed on the ends of the nanostructures 55 have a triangular shape when viewed from a side cross-sectional view. For example, FIG. 11C illustrates an embodiment, in which a third semiconductor material 192a epitaxially formed on the nanostructures 54 has a quadrilateral geometry, e.g., four sided cross-section. The quadrilateral geometry may be achieved by an epitaxial deposition process, in which the temperature of the epitaxial deposition process is greater than 600° C.

Referring back to FIG. 11B, following the formation of the first semiconductor material, the p-type region 50P may be processed to form the interface semiconductor material 194. The interface semiconductor material 194 may also be composed of silicon germanium (SiGe). The interface semiconductor material 194 may be formed using an epitaxial growth process, and may have a conformal thickness, as depicted in FIG. 11B. Due to the use of an epitaxial deposition process, the interface semiconductor material may have a (110) crystalline orientation. In some embodiments, the epitaxial growth process forms an interface semiconductor material 194 having a silicon germanium (SiGe) material having a germanium (Ge) content that is greater than the germanium (Ge) concentration of the silicon germanium (SiGe) of the first semiconductor material 192. For example, the silicon germanium (SiGe) composition of the interface semiconductor material 194 may be Si₁₋ₓGeₓ, in which 0.1<x<0.4,

The interface semiconductor material 194 for the p-type region 50P may be doped with a p-type dopant. For example, for a group IV semiconductor, such as silicon (Si) and silicon germanium (SiGe), examples of p-type dopants can include boron, indium, and/or gallium. In some embodiments, the concentration of the p-type dopant for the interface semiconductor material 194 is more than the concentration of the first semiconductor material 192. However, in some embodiments, the concentration of the p-type dopant for the interface semiconductor material 194 is greater than the concentration of the first semiconductor material 192. For example, the p-type dopant concentration of the interface semiconductor material 194 is equal to 7×10²⁰ cm⁻³ or less.

The interface semiconductor material 194 can be a conformal thickness material layer. In some embodiments, the interface semiconductor material 194 can have a conformal thickness T2 ranging from 1 nm to 10 nm. In one example, the interface semiconductor material 194 has a thickness T2 ranging from 2 nm to 6 nm. However, it is not necessary that the interface semiconductor material 194 may a conformally deposited material. For example, FIG. 11D illustrates one embodiment of an interface semiconductor material 194 having a non-conformal thickness. In some embodiments, the non-conformal thickness for the interface semiconductor material 194 depicted in FIG. 11D may be provided by an epitaxial deposition process, in which the temperature of the epitaxial deposition process is at a temperature ranging from 600° C. to 800° C. Additionally, the interface semiconductor material 194 does not necessary have to be formed using an epitaxial deposition process. In some embodiments, the interface semiconductor material 194 may be formed from co-diffusion of elements from the first semiconductor material 192 and the second semiconductor material 193. The interface semiconductor material 194 is positioned at the interface between the first semiconductor material 192 and the second semiconductor material 193. In some embodiments, the co-diffusion of elements may be facilitated by annealing.

FIG. 11B also illustrates the second semiconductor material 193 filling the trench that is provided by the first recesses 86. In some embodiments, the second semiconductor material 193 is in direct contact with the interface semiconductor material 194. In some embodiments, the second semiconductor material 193 fills the entirety of the trench. Similar to the first semiconductor material 192, the second semiconductor material is an epitaxially deposited (epitaxially formed) material, and may be composed of silicon germanium (SiGe). The silicon germanium (SiGe) gas precursors described above for forming the first semiconductor material 192 can be equally applicable for forming the second semiconductor material 193. However, the concentration of germanium in the second semiconductor material 193 is greater than the concentration of germanium in the first semiconductor material 192. For example, the concentration of germanium (Ge) in the silicon germanium (SiGe) for the second semiconductor material 193 may be selected to provide Si₁₋ₓGeₓ, in which 0.4<x<0.6. The germanium concentration of the second semiconductor material 193 is also greater than the germanium concentration in the interface semiconductor material 194.

The second semiconductor material 193 for the p-type region 50P may be doped with a p-type dopant. For example, for a group IV semiconductor, such as silicon (Si) and silicon germanium (SiGe), examples of p-type dopants can include boron, indium, and/or gallium. In some embodiments, the concentration of the p-type dopant for the second semiconductor material 193 is more than the concentration of the first semiconductor material 192. In some embodiments, the concentration of the p-type dopant for the second semiconductor material 193 is also greater than the concentration of the interface semiconductor material 194. For example, the p-type dopant concentration of the second semiconductor material 193 is greater than 7×10²⁰ cm⁻³.

The second semiconductor material 193 is epitaxially formed on the interface semiconductor material 194 and is present over the first semiconductor material 192. In some embodiments, the first semiconductor material 192 in at least the upper portion of the trench, and the interface semiconductor material 194 having the conformal thickness formed on the first semiconductor material 192 have a triangular cross-sectional geometry when viewed from a side cross-sectional view, as depicted in FIG. 11B. These geometric features are present on both sides of the trench, which is provided by the first opening 86. This provides that the uppermost portion of the trench has a greater width when compared to the underlying portions of the trench at which the apex portion of the triangular cross-sections provided by the first and interface semiconductor material 192, 194 are present. The second semiconductor material 194 fills this wide upper portion of the trench. In some embodiments, beginning at the uppermost portion of the trench, the second semiconductor material 193 has a width with a reducing taper from an uppermost portion of the trench until reaching the portion of the trench at which the first apex of the triangular geometry first semiconductor material 192 (and interface semiconductor material 194) is positioned. At the portions of the trench having the first apex of the triangular cross-sectional geometry of the first semiconductor material 192, the width of the second semiconductor material 193 may be its narrowest. In some embodiments, the wide portion of the second semiconductor material 193 in the upper portion of the trench provides a wide landing point for the later formed contact and associated metal semiconductor alloy (e.g., silicide). Further, as will be described later, because the second semiconductor material 193 has the highest germanium concentration and highest p-type dopant concentration for the source/drain regions in the p-type regions 50 of the device, the contact formed to the wide landing portion has a lower resistance, e.g., lower contact resistance, than a contact that would be formed in contact with the interface semiconductor material 194 and/or the first semiconductor material 192. By providing the second semiconductor material 193 having a widest, lowest resistance portion in the uppermost portion of the trench, the second semiconductor material 193 provides a low resistance landing point for the later formed contacts to the source/drain regions in the p-type region 50P of the device.

FIG. 11E illustrates another embodiment of the source/drain region 92 for the p-type region 50p of the device. In the embodiment depicted in FIG. 11E, the upper portion of the trench includes first semiconductor material 192 having the triangular geometry when viewed from a side cross-sectional view. However, the semiconductor material that is present in direct contact with the second nanostructures 54 does not necessarily have to have a triangular geometry. For example, a third semiconductor material 192a may be epitaxially formed on the second nanostructures 54 at a lower portion of the trench that has a different cross-section from the triangular geometry of the first semiconductor material 192 (see e.g., FIG. 18C). For example, the third semiconductor material 192a at the lower portion of the trench can have a quadrilateral geometry when viewed from a side cross-sectional view. The geometry of the semiconductor material formed on the second nanostructures 54 may be adjusted by adjusting the temperature of the epitaxial growth process for forming the first semiconductor material 192, and the third semiconductor material 192a. For example, to provide that the first semiconductor material 192 having the triangular geometry in the upper portion of the trench, the temperature of the epitaxial deposition process is limited to less than 600° C. For example, to provide the third semiconductor material 192a having the quadrilateral geometry below the upper portion of the trench, the temperature of the epitaxial deposition process may be in a temperature ranging from 600° C. to 800° C. In some embodiments, masking and selective etching may be employed to dictate the location of the epitaxial material within the trench. For example, a first epitaxial deposition may be performed using a temperature ranging from 600° C. to 800° C. to provide the third semiconductor material 192a having the quadrilateral geometry when viewed from a side cross-section. To remove the third semiconductor material 192a having the quadrilateral geometry from the upper section of the trench, a mask, e.g., photoresist mask, can be formed over the third semiconductor material 192a in the bottom of the trench leaving the third semiconductor material having the quadrilateral geometry exposed in an upper portion of the trench. The exposed portion of the third semiconductor material having the quadrilateral geometry may then be removed using an etch selective to the second nanostructures 54. Thereafter, the first semiconductor material 192 having the triangular geometry may be formed on the exposed ends of the second nanostructures 54 in the upper portion of the trench using a low temperature epitaxial deposition, e.g., in which the epitaxial deposition temperature is 600° C. or less. The masking may then be removed, and the remaining epitaxial materials to fill the trench may then be formed. FIG. 11E illustrates one embodiment of the an epitaxial semiconductor material having a first concentration of germanium on ends of nanostructures 54 at sidewalls of the trench include a first semiconductor material 192 having the triangular geometry at an upper portion of the trench, wherein a third semiconductor material 192a is present below the upper portion of the trench and has a quadrilateral geometry when viewed from a side cross-sectional view. The first semiconductor material 192 and the third semiconductor material 192a may have the same material composition, e.g., be silicon germanium (SiGe) having the same germanium (Ge) concentration. The first semiconductor material 192 and the third semiconductor material 192a may also be doped with the same conductivity type dopant, e.g., p-type dopant, and may have the same composition of p-type dopant.

The source/drain regions 92 depicted in FIGS. 11B-11E are for p-type doped source/drain regions that are present in the p-type region 50P. The source/drain regions 92 of the n-type region 50N may be independently processed. To provide that the source/drain regions 92 in the p-type and n-type regions 50P, 50N are independently processed block masks may be employed. In the remainder of the figures until FIGS. 18B and 18C, the source/drain regions will be identified by reference number 92 regardless of being processed for p-type or n-type regions 50P, 50N.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 11F. In other embodiments, adjacent epitaxial source/drain regions 92 remain separated after the epitaxy process is completed as illustrated by FIG. 11G. In the embodiments illustrated in FIGS. 11F and 11G, the fin spacers 83 may be formed on top surfaces of the STI regions 86, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI structures 68.

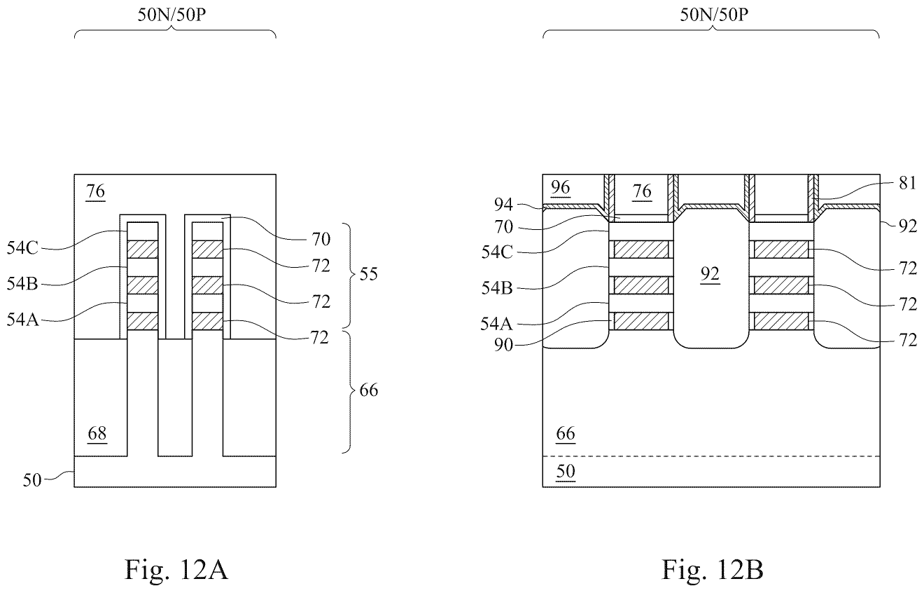

In FIGS. 12A and 12B, a first interlayer dielectric (ILD) 96 is deposited over the structure illustrated in FIGS. 18A and 19B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

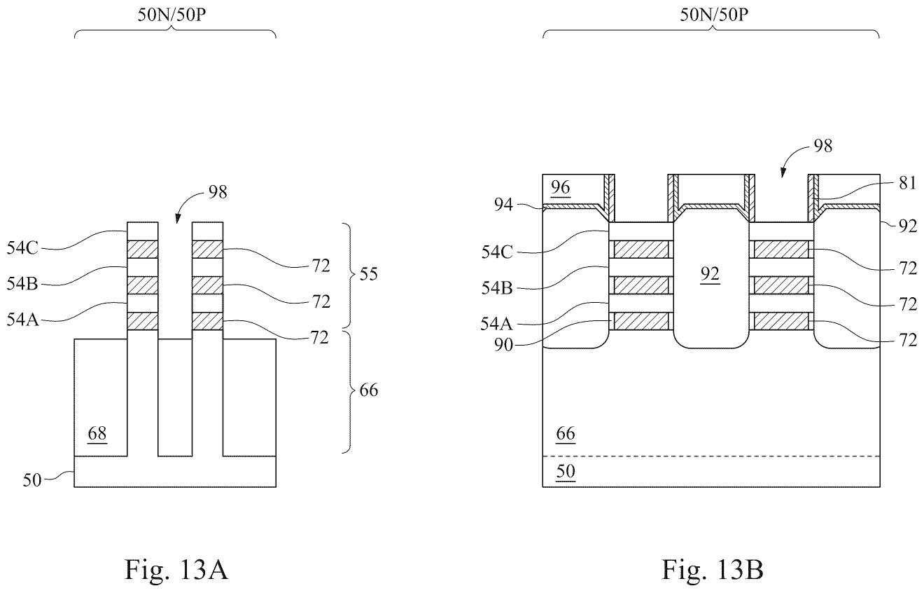

In FIGS. 13A and 13B, the dummy gates 76, and the masks 78 if present, are removed in one or more etching steps, so that second recesses 98 are formed. Portions of the dummy gate dielectrics 70 and portions of the protective liner 60 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

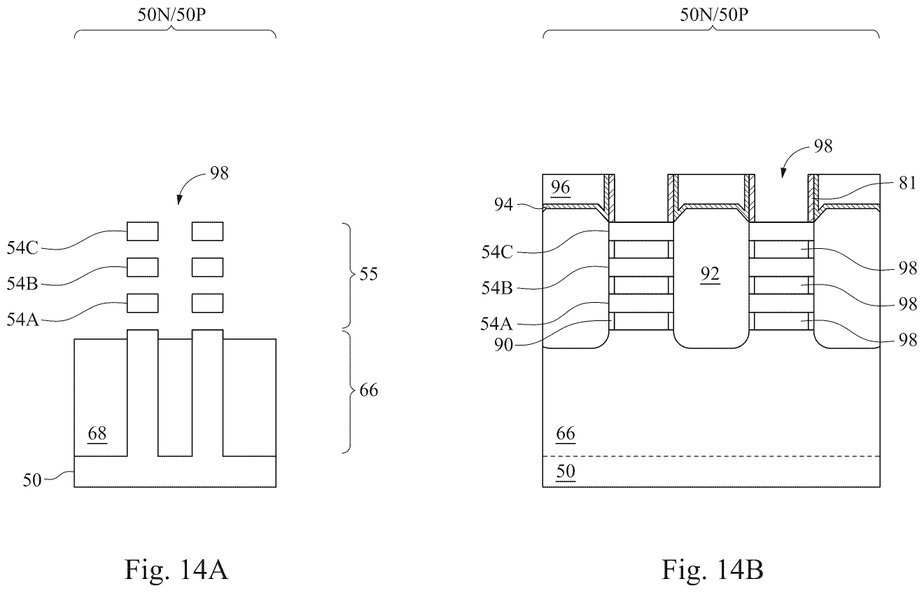

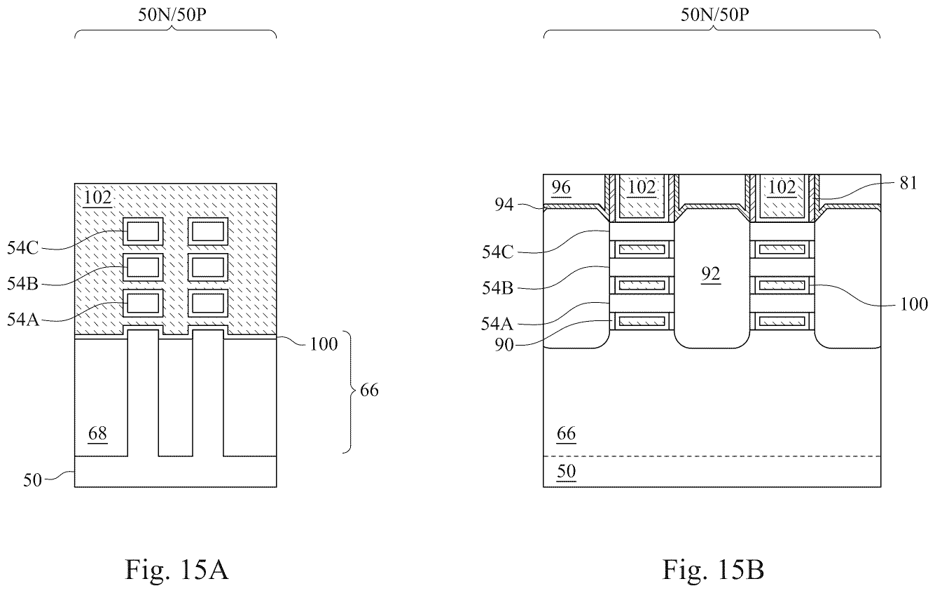

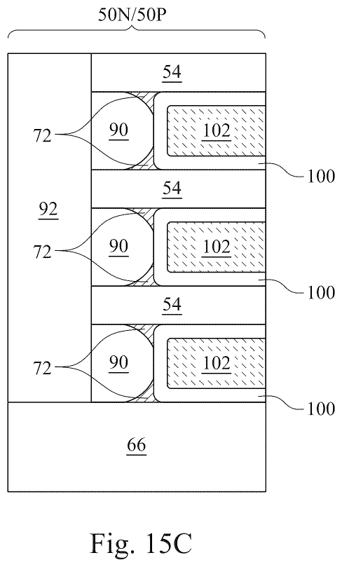

In FIGS. 14A and 14B, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. The sacrificial material 72 may be completely removed, or a residue of the sacrificial material 72 may remain on sidewalls of the inner spacers in the second recesses 98 (see e.g., FIG. 15C).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may comprise, for example, a nitride.

In FIGS. 15A-15C, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 15A-15C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 15C illustrates a detailed view of various elements of FIG. 15B, including the epitaxial source/drain regions 92, the gate dielectric layers 100, the gate electrodes 102, the second nanostructures 54, and the inner spacers 90. In some embodiments, illustrated by FIG. 15C, a residue of the sacrificial material 72 may remain on the inner spacers 90, such as between the inner spacers 90 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

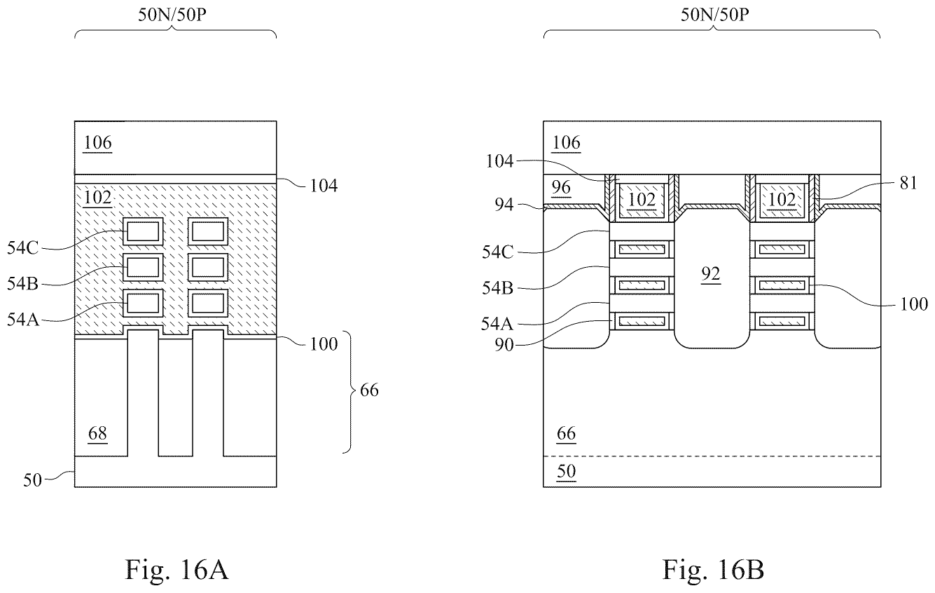

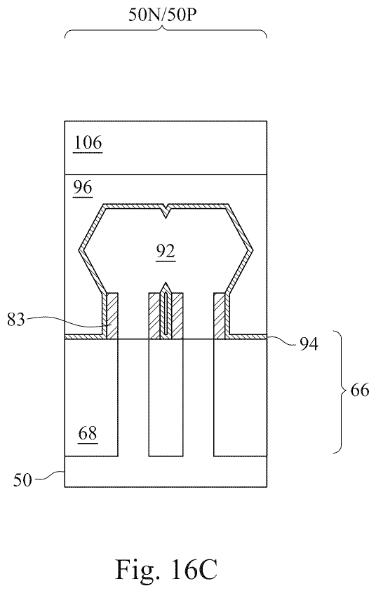

In FIGS. 16A-16C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 18A-18C) penetrate through the gate mask 104 to contact the top surface of the recessed gate electrodes 102.

As further illustrated by FIGS. 16A-16C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

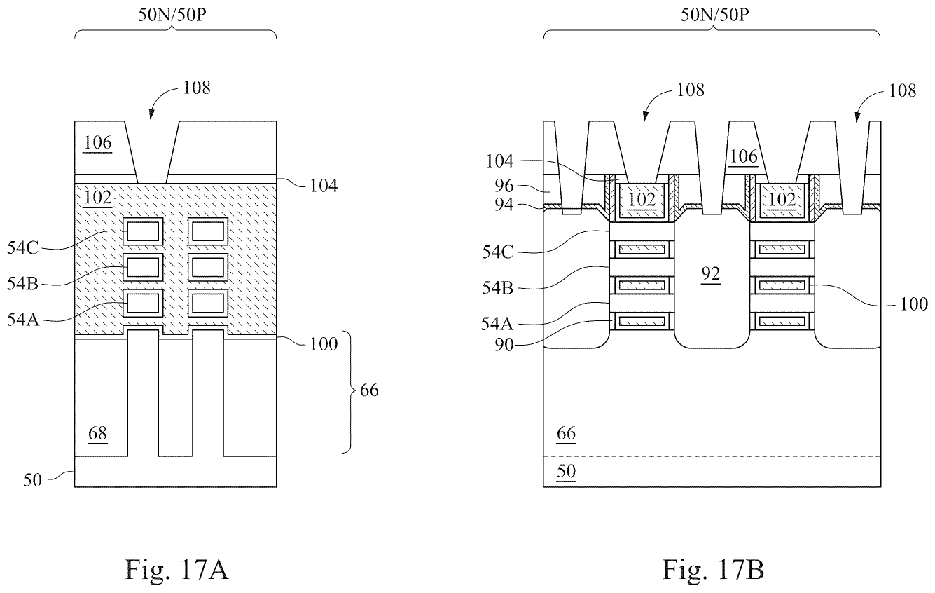

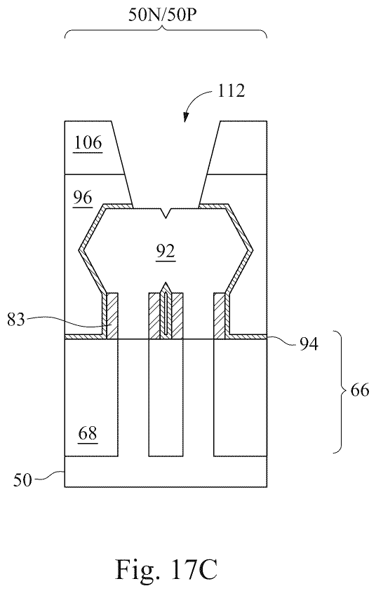

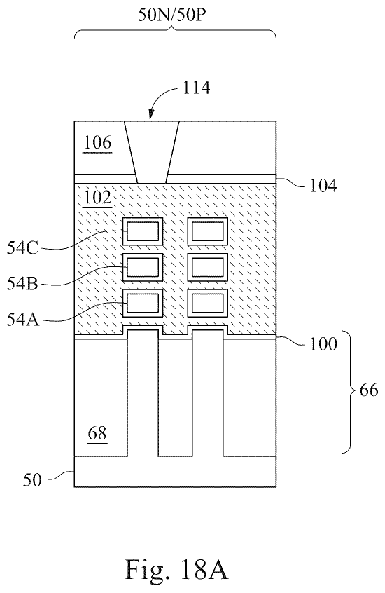

In FIGS. 17A-17C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure.

FIGS. 18A-18C illustrate forming contacts 118. After the third recesses 108 are formed, silicide regions are formed over the epitaxial source/drain regions 92. For the source/drain regions in the p-type region 50P, the contacts 118 are formed to the second semiconductor material 193 in the upper portion of the trench that has the widest landing surface for the contact 118. For example, the metal contact lands on epitaxial material having a highest concentration of germanium. In some embodiments, the larger contact area on high germanium concentration portions of the p-type epitaxial material of the second semiconductor material 193 for the source/drain regions 92 result in lower contact resistivity. The contacts 118 for the source/drain regions 92 of the p-type region 50P do not extend into the interface semiconductor material 194 or the first semiconductor material 192, 192a, which each have a lower concentration of germanium (Ge) and p-type dopant than the second semiconductor material 193. Due to the lower concentration of germanium (Ge) and p-type dopant, e.g., boron (B), in the p-type region 50P, the first semiconductor material 192, 192a, and the interface semiconductor material 194 have a higher resistance than the second semiconductor material 193. For this reason, the contacts 118 to the source/drain regions 92 in the p-type region 50P directly contact the second semiconductor material 193 in the uppermost portion of the trench, wherein the contact 118 does not extend into the first semiconductor material 192, or the interface semiconductor material 194. The contacts to the source/drain regions 92 in the p-type region 50N are formed to the upper surface of the n-type doped semiconductor material of the source/drain regions in the n-type region 50N.

FIG. 18B illustrates forming a contact 118 to the second semiconductor material 193 of the source/drain region 92 depicted in FIG. 11B. In FIG. 18B, the first semiconductor material 192 having the triangular geometry when viewed from the side cross-sectional view is present on the edges of the nanostructures 54 for both the upper and lower portions of the trench. FIG. 18C illustrates forming a contact 118 to the second semiconductor material 193 of the source/drain depicted in FIG. 11E. In FIG. 18B, the first semiconductor material 192 having the triangular geometry when viewed from the side cross-sectional view is present on the edges of the nanostructures 54 in the upper portion of the trench. In the embodiment depicted in FIG. 18B, the epitaxial semiconductor material on the nanostructures 54 at the upper portion of the nanostructure stack may have a triangular geometry, and the epitaxial semiconductor on the nanostructures 54 at the lower portion of the nanostructure stack may have a quadrilateral geometry. In FIG. 18C, a third semiconductor material 192a that is present in the lower portion of the trench has a quadrilateral geometry when viewed from a side cross-sectional view.

In some embodiments, before forming the contacts 118, silicide regions are formed by depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, and then performing a thermal anneal process to form the silicide regions. The un-reacted portions of the deposited metal are then removed, e.g., by an etching process. Although silicide regions are referred to as silicide regions, silicide regions may also be germanide regions, or silicon germanide regions (e.g., regions comprising silicide and germanide). For example, silicon germanide regions may be formed on the contact surface of the second semiconductor material 193 in the p-type region 50P.

Next, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions and may be referred to as source/drain contacts. In some embodiments, the conductivity of the silicide that provides the contacts 112 is greater than the conductivity of the source/drain regions. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

In some embodiments, the above method can produce a semiconductor device including nanostructure, e.g., nanosheet, channel regions and a gate all around (GAA) gate structure that includes a substrate t0 having a (110) crystal orientation, a stack of nanostructures 54 over the substrate 50, and a source/drain region 92 in trenches on opposing sides of the stack of nanostructures 54. The source/drain region 92 includes a first semiconductor material 192 having a first concentration of germanium on ends of the nanostructures 54 in the stack of nanostructures. The first semiconductor material 192 has a triangular geometry when viewed from a side cross sectional view, and a second semiconductor material 193 having a second concentration of germanium on the first semiconductor material 192. The second semiconductor material 193 filling at least a portion of the trenches. In some embodiments, the second concentration of the germanium in the second semiconductor material 193 is greater than the first concentration of the germanium in the first semiconductor material 192. In some embodiments, the first semiconductor material 192 that has the triangular geometry when viewed from a side cross sectional view is present in both the upper and lower portions of the trench, as depicted in FIG. 18B. In some other embodiments, the first semiconductor material 192 that has the triangular geometry when viewed from the side cross-sectional view is only present in an upper portion of the trench, wherein below the upper portion of the trench the epitaxial semiconductor material that is on the nanostructures 54 may have a quadrilateral geometry. For example, a third semiconductor material 192a having the quadrilateral geometry when viewed from a side cross-sectional view can be present on the nanostructures 54 in the lower portion of the trench, as depicted in FIG. 18C. The nanostructures 54 for the p-type devices in the p-type regions 50P provide the channel regions of the devices and are composed of (110) crystalline orientation silicon. Further the nanostructures 54 are configured to be between source/drain regions orientated along a <110> direction (also referred to as fin direction).

In various embodiments, the methods and structures that are described herein employ a (110) substrate to provide for enhanced minority charger carrier mobility, and provides a further performance benefit by controlling epitaxially deposited shapes in PMOS source/drain region on (110). For example, for the epitaxially deposited material for the source/drain regions, the shape of the epitaxially deposited material can be controlled from a rectangle geometry to a triangular geometry by adjusting the process conditions of the epitaxial growth process. By controlling the shape of the epitaxial material the contact surfaces of the metal contact for the source/drain regions may be maximized to provide that the metal contact lands on epitaxial material having a highest concentration of germanium. In some embodiments, the larger contact area on high germanium concentration portions of the p-type epitaxial material of the source/drain regions result in lower contact resistivity.

In some embodiments, a method is described that includes: forming a trench through a nanostructure stack over a (110) orientation substrate, the nanostructure stack comprising first nanostructures; epitaxially forming a first semiconductor material having a first concentration of germanium on sidewalls of the first nanostructures in the trench, wherein the first semiconductor material has a triangular geometry in a cross sectional view; epitaxially forming a second semiconductor material having a second concentration of germanium on the first semiconductor material, the second semiconductor material having a width with a reducing taper from an uppermost portion of the trench, wherein the second concentration of the germanium is greater than the first concentration of the germanium; and forming a contact to the second semiconductor material. In an embodiment, the method can further include an interface semiconductor material in direct contact with the first semiconductor material and the second semiconductor material, wherein an interface germanium concentration of the interface semiconductor material is between the first concentration and the second concentration. In some embodiments, the contact to the second semiconductor material does not extend past the second semiconductor material having the second concentration of germanium. In some embodiments, the first semiconductor material and the second semiconductor material are doped with a p-type dopant. In some embodiments, the first concentration of the p-type dopant in the first semiconductor material is less than a second concentration of the p-type dopant in second semiconductor material. In some embodiments, the triangular geometry has a base angle ranging from 35 degrees to 55 degrees. For example, the triangular geometry may have a base angle of 45 degrees, e.g., 45 degrees+/−10 degrees.

In another embodiment, the method can include: forming a trench through a nanostructure stack over a (110) orientation substrate, the nanostructure stack comprising first nanostructures; epitaxially forming a first semiconductor material having a first concentration of germanium on sidewalls of the first nanostructures in the trench, wherein an epitaxial growth temperature of the first semiconductor material is limited to a maximum of 600° C., and the first semiconductor material has a triangular geometry in a cross sectional view; epitaxially forming a second semiconductor material having a second concentration of germanium on the first semiconductor material to fill at least a portion of the trench; and forming a contact to the second semiconductor material, wherein the contact does not extend into the first semiconductor material. In an embodiment, an interface semiconductor material in direct contact with the first semiconductor material and the second semiconductor material, wherein an interface germanium concentration of the interface semiconductor material is between the first concentration and the second concentration. In an embodiment, the contact to the second semiconductor material does not extend past the second semiconductor material. In an embodiment, the triangular geometry has a base angle ranging from 35 degrees to 55 degrees. In an embodiment, the method further includes forming a third semiconductor material on the first nanostructures in a lower portion of the trench, the third semiconductor material having a quadrilateral geometry in a cross sectional view, wherein the first semiconductor material is formed in an upper portion of the trench after forming the third semiconductor material. In an embodiment, the quadrilateral geometry of the third semiconductor material is formed using an epitaxial deposition process having a temperature greater than 600° C.

In another aspect, a semiconductor device is described that includes: a substrate having a (110) crystal orientation; a stack of nanostructures over the substrate; and source/drain regions on opposing sides of the stack of nanostructures. In some embodiments, each of the source/drain regions includes: a first semiconductor material having a first concentration of germanium on ends of the nanostructures in the stack of nanostructures, wherein the first semiconductor material has a triangular geometry when viewed from a cross-sectional view; and a second semiconductor material having a second concentration of germanium on the first semiconductor material, the second concentration of germanium is greater than the first concentration of the germanium. In some embodiments, the source/drain regions are doped to a p-type conductivity. In some embodiments, the stack of nanostructures is configured to provide that p-type charge carriers travel along a <110> direction. In some embodiments, the semiconductor device further includes an interface semiconductor material in direct contact with the first semiconductor material and the second semiconductor material, wherein an interface germanium concentration of the interface semiconductor material is between the first concentration of germanium and the second concentration of germanium. In some embodiments, the semiconductor device further includes a contact to the second semiconductor material wherein the contact to the second semiconductor material does not extend past the second semiconductor material. In some embodiments, the first semiconductor material and the second semiconductor material are doped with a p-type dopant, wherein a first concentration of the p-type dopant is present in the first semiconductor material in a lower concentration than a second concentration of the p-type dopant that is second semiconductor material. In some embodiments, the triangular geometry has a base angle ranging from 35 degrees to 55 degrees. In some embodiments, the first semiconductor material having a first concentration of germanium on ends of nanostructures in an upper portion of the stack of nanostructures, wherein a third semiconductor material having the first concentration of germanium is on ends of nanostructures in a lower portion of the stack of nanostructures, wherein the third semiconductor material has a quadrilateral geometry when viewed from a cross-sectional view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a trench through a nanostructure stack over a (110) orientation substrate, the nanostructure stack comprising first nanostructures;
epitaxially forming a first semiconductor material having a first concentration of germanium on sidewalls of the first nanostructures in the trench, wherein the first semiconductor material has a triangular geometry in a cross sectional view;
epitaxially forming a second semiconductor material having a second concentration of germanium on the first semiconductor material, the second semiconductor material having a width with a reducing taper from an uppermost portion of the trench, wherein the second concentration of the germanium is greater than the first concentration of the germanium; and
forming a contact to the second semiconductor material.

2. The method of claim 1, further comprising an interface semiconductor material present in contact with the first semiconductor material and the second semiconductor material, wherein an interface germanium concentration of the interface semiconductor material is between the first concentration and the second concentration.

3. The method of claim 1, wherein the contact to the second semiconductor material does not extend past the second semiconductor material having the second concentration of germanium.

4. The method of claim 1, wherein the first semiconductor material and the second semiconductor material are doped with a p-type dopant.

5. The method of claim 4, wherein a first concentration of the p-type dopant in the first semiconductor material is less than a second concentration of the p-type dopant in second semiconductor material.

6. The method of claim 1, wherein the triangular geometry has a base angle ranging from 35 degrees to 55 degrees.

7. A method comprising:
forming a trench through a nanostructure stack over a (110) orientation substrate, the nanostructure stack comprising first nanostructures;
epitaxially forming a first semiconductor material having a first concentration of germanium on sidewalls of the first nanostructures in the trench, wherein an epitaxial growth temperature of the first semiconductor material is limited to a maximum of 600° C., and the first semiconductor material has a triangular geometry in a cross sectional view;
epitaxially forming a second semiconductor material having a second concentration of germanium on the first semiconductor material to fill at least a portion of the trench; and
forming a contact to the second semiconductor material, wherein the contact does not extend into the first semiconductor material.

8. The method of claim 7, further comprising an interface semiconductor material in contact with the first semiconductor material and the second semiconductor material, wherein an interface germanium concentration of the interface semiconductor material is between the first concentration and the second concentration.

9. The method of claim 7, wherein the contact to the second semiconductor material does not extend past the second semiconductor material.

10. The method of claim 7, wherein the triangular geometry has a base angle ranging from 35 degrees to 55 degrees.

11. The method of claim 7, further comprising forming a third semiconductor material on the first nanostructures in a lower portion of the trench, the third semiconductor material having a quadrilateral geometry in a cross sectional view, wherein the first semiconductor material is formed in an upper portion of the trench after forming the third semiconductor material.

12. The method of claim 11, wherein the quadrilateral geometry of the third semiconductor material is formed using an epitaxial deposition process having a temperature greater than 600 ° C.

13. A semiconductor device comprising:
a substrate having a (110) crystal orientation;
a stack of nanostructures over the substrate; and
source/drain regions on opposing sides of the stack of nanostructures, wherein each of the source/drain regions includes:
a first semiconductor material having a first concentration of germanium on ends of the nanostructures in the stack of nanostructures, wherein the first semiconductor material has a triangular geometry when viewed from a cross-sectional view; and
a second semiconductor material having a second concentration of germanium on the first semiconductor material, the second concentration of germanium is greater than the first concentration of the germanium.

14. The semiconductor device of claim 13, wherein the source/drain regions are doped to a p-type conductivity.

15. The semiconductor device of claim 13, wherein the stack of nanostructures is configured to provide that p-type charge carriers travel along a <110> direction.

16. The semiconductor device of claim 13, further comprising an interface semiconductor material in direct contact with the first semiconductor material and the second semiconductor material, wherein an interface germanium concentration of the interface semiconductor material is between the first concentration of germanium and the second concentration of germanium.

17. The semiconductor device of claim 13, further comprising a contact to the second semiconductor material wherein the contact to the second semiconductor material does not extend past the second semiconductor material.

18. The semiconductor device of claim 13, wherein the first semiconductor material and the second semiconductor material are doped with a p-type dopant, wherein a first concentration of the p-type dopant is present in the first semiconductor material in a lower concentration than a second concentration of the p-type dopant that is second semiconductor material.

19. The semiconductor device of claim 13, wherein the triangular geometry has a base angle ranging from 35 degrees to 55 degrees.

20. The semiconductor device of claim 13, wherein the first semiconductor material having a first concentration of germanium on ends of nanostructures in an upper portion of the stack of nanostructures, wherein a third semiconductor material having the first concentration of germanium is on ends of nanostructures in a lower portion of the stack of nanostructures, wherein the third semiconductor material has a quadrilateral geometry when viewed from a cross-sectional view.
